(19) United States
(12) Patent Application Publication
(10) Pub. No.: US 2025/0096748 A1
(43) Pub. Date: Mar. 20, 2025

(54) MULTI-MODE POWER MANAGEMENT APPARATUS

(71) Applicant: Qorvo US, Inc., Greensboro, NC (US)

(72) Inventor: Nadim Khlat, Cugnaux (FR)

(21) Appl. No.: 18/966,259

(22) Filed: Dec. 3, 2024

Related U.S. Application Data
(63) Continuation of application No. 17/629,759, filed on Jan. 24, 2022.
(60) Provisional application No. 62/878,358, filed on Jul. 25, 2019.

(51) Int. Cl. H03F 3/195; H03F 1/02; H03F 3/24; H03F 3/72

(52) U.S. Cl. CPC H03F 3/195; H03F 1/0227; H03F 3/245; H03F 3/72; H03F 2200/102; H03F 2200/451

(57) ABSTRACT

A multi-mode power management apparatus is provided. In embodiments disclosed herein, the multi-mode power management apparatus can be configured to operate in different power management modes across a wide range of modulation bandwidth (e.g., 80 KHz to over 200 MHz). The multi-mode power management apparatus includes a power management integrated circuit (PMIC) and an envelope tracking integrated (ET) circuit (ETIC), which are implemented in separate dies. The PMIC is configured to generate a low-frequency current and a low-frequency voltage. The ETIC is configured to generate a pair of ET voltages. Depending on the power management mode, the multi-mode power management apparatus can selectively output one or more of the ET voltages and the low-frequency voltage to different stages (e.g., driver stage and output stage) of a power amplifier circuit, thus helping to maintain optimal efficiency and linearity of the power amplifier circuit across the wide range of modulation bandwidth.

### RELATED APPLICATIONS

This application a continuation of U.S. patent application Ser. No. 17/629,759, filed on Jan. 24, 2022, which is a 35 USC 371 national phase filing of International Application No. PCT/US2020/043067, filed Jul. 22, 2020, which claims the benefit of U.S. provisional patent application Ser. No. 62/878,358, filed Jul. 25, 2019, the disclosures of which are hereby incorporated herein by reference in their entireties.

### FIELD OF THE DISCLOSURE

The technology of the disclosure relates generally to a power management apparatus.

### BACKGROUND

Mobile communication devices, such as smartphones, have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience has also led to the rise of so-called wearable devices, such as smartwatches. Over time, these wearable devices have evolved from simple companion devices to mobile communication devices into full-fledged multi-functional wireless communication devices. Nowadays, most wearable electronic devices are often equipped with digital and analog circuitries capable of communicating a radio frequency (RF) signal(s) in a variety of wireless communication systems, such as long-term evolution (LTE), Wi-Fi, Bluetooth, and so on. Like mobile communication devices, wearable devices often employ sophisticated power amplifiers to amplify RF signal(s) to help improve coverage range, data throughput, and reliability of the wearable devices.

Envelope tracking (ET) is a power management technology designed to improve efficiency levels of power amplifiers. In this regard, it may be desirable to employ ET across a variety of wireless communication technologies to help reduce power consumption and thermal dissipation in wearable devices. Notably, the RF signal(s) communicated in different wireless communication systems may correspond to different modulation bandwidths (e.g., from 80 KHz to over 200 MHZ). As such, it may be further desirable to ensure that the power amplifiers can maintain optimal efficiency and linearity across a wide range of modulation bandwidth.

### Summary

Embodiments of the disclosure relate to a multi-mode power management apparatus. In embodiments disclosed herein, the multi-mode power management apparatus can be configured to operate in different power management modes across a wide range of modulation bandwidth (e.g., 80 KHz to over 200 MHz). The multi-mode power management apparatus includes a power management integrated circuit (PMIC) and an envelope tracking integrated (ET) circuit (ETIC), which are implemented in separate dies. The PMIC is configured to generate a low-frequency current and a low-frequency voltage. The ETIC is configured to generate a pair of ET voltages. Depending on the power management mode, the multi-mode power management apparatus can selectively output one or more of the ET voltages and the low-frequency voltage to different stages (e.g., driver stage and output stage) of a power amplifier circuit, thus helping to maintain optimal efficiency and linearity of the power amplifier circuit across the wide range of modulation bandwidth.

In one aspect, a multi-mode power management apparatus is provided. The multi-mode power management apparatus includes a PMIC configured to generate a low-frequency current and a low-frequency voltage. The multi-mode power management apparatus also includes an ETIC. The ETIC includes a first node coupled to the PMIC. The ETIC also includes a second node coupled to the first node via a multifunction circuit. The ETIC also includes a first voltage circuit configured to generate a first ET voltage based on a first ET target voltage. The ETIC also includes a second voltage circuit configured to generate a second ET voltage based on a second ET target voltage. The ETIC also includes a control circuit. The control circuit is configured to cause the first node and the second node to output one or more of the first ET voltage, the second ET voltage, and the low-frequency voltage. The control circuit is also configured to cause the first node and the second node to output at least the low-frequency current.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary multi-mode power management apparatus according to an embodiment of the present disclosure; and

FIG. 2 is a schematic diagram illustrating a detailed configuration of the multi-mode power management apparatus of FIG. 1 in different power management modes.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a multi-mode power management apparatus. In embodiments disclosed herein, the multi-mode power management apparatus can be configured to operate in different power management modes across a wide range of modulation bandwidth (e.g., 80 KHz to over 200 MHz). The multi-mode power management apparatus includes a power management integrated circuit (PMIC) and an envelope tracking integrated (ET) circuit (ETIC), which are implemented in separate dies. The PMIC is configured to generate a low-frequency current and a low-frequency voltage. The ETIC is configured to generate a pair of ET voltages. Depending on the power management mode, the multi-mode power management apparatus can selectively output one or more of the ET voltages and the low-frequency voltage to different stages (e.g., driver stage and output stage) of a power amplifier circuit, thus helping to maintain optimal efficiency and linearity of the power amplifier circuit across the wide range of modulation bandwidth.

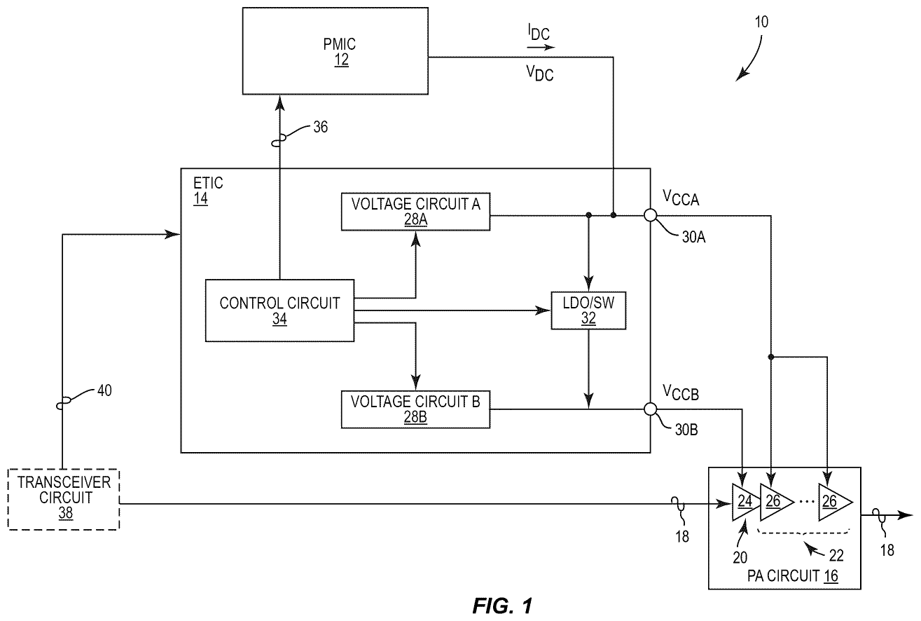

FIG. 1 is a schematic diagram of an exemplary multi-mode power management apparatus 10 configured according to an embodiment of the present disclosure. The multi-mode power management apparatus 10 includes a PMIC 12 and an ETIC 14 that are provided in separate dies. The multi-mode power management apparatus 10 may include or be coupled to a multi-stage power amplifier circuit 16 configured to amplify a radio frequency (RF) signal 18. The multi-stage power amplifier circuit 16 may include a driver stage 20 and an output stage 22. In a non-limiting example, the driver stage 20 includes a power amplifier 24 and the output stage 22 includes one or more power amplifiers 26.

In examples discussed herein, the multi-mode power management apparatus 10 can be configured to operate in different power management modes, depending on modulation bandwidth of the RF signal 18. In a non-limiting example, the multi-mode power management apparatus 10 operates in a first power management mode when the modulation bandwidth is greater than 160 MHZ (>160 MHz), a second power management mode when the modulation bandwidth is between 1 MHz and 160 MHZ (>1 MHz and ≤160 MHz), a third power management mode when the modulation bandwidth is between 120 KHz and 1 MHz (>120 KHz and ≤1 MHZ), a fourth power management mode when the modulation bandwidth is between 80 KHz and 120 KHz (>80 KHz and ≤120 KHz), or a fifth power management mode when the modulation bandwidth is below 80 KHz (≤80 KHz). Thus, by operating in different power management modes based on the modulation bandwidth of the RF signal 18, the multi-mode power management apparatus 10 can maintain optimal efficiency and linearity of the multi-stage power amplifier circuit 16 across a wide range of modulation bandwidth.

The PMIC 12 is configured to generate a low-frequency voltage V_{DC} (e.g., a constant voltage or a modulated constant voltage) and a low-frequency current I_{DC} (e.g., a direct current or a modulated direct current). The ETIC 14 includes a first voltage circuit 28A configured to generate a first ET voltage V_{CCA} and a second voltage circuit 28B configured to generate a second ET voltage V_{CCB}. The ETIC 14 includes a first node 30A and a second node 30B, which may be coupled to the output stage 22 and the driver stage 20 of the multi-stage power amplifier circuit 16, respectively. The first node 30A is coupled to the first voltage circuit 28A and the PMIC 12. The second node 30B is coupled to the second voltage circuit 28B and to the first node 30A via a multifunction circuit 32 (denoted as “LDO/SW”). In a non-limiting example, the multifunction circuit 32 may include a low dropout (LDO) and a switch (not shown).

The ETIC 14 includes a control circuit 34, which can be any type of microcontroller, or a field-programmable gate array (FPGA), as an example. It should be appreciated that functionality of the control circuit 34 may be shared between multiple control circuits and/or controllers without affecting functionality and operation of the multi-mode power management apparatus 10.

The control circuit 34 is coupled to the first voltage circuit 28A, the second voltage circuit 28B, and the multifunction circuit 32. As discussed in detail below, the control circuit 34 can individually or collectively control the first voltage circuit 28A, the second voltage circuit 28B, and the multifunction circuit 32 to cause the first node 30A and the second node 30B to output one or more of the low-frequency voltage V_{DC}, the first ET voltage V_{CCA}, and the second ET voltage V_{CCB} in the different power management modes. In addition, the control circuit 34 can also individually or collectively control the first voltage circuit 28A, the second voltage circuit 28B, and the multifunction circuit 32 to cause the first node 30A and the second node 30B to output at least the low-frequency current I_{DC} in the different power management modes.

The control circuit 34 may provide a feedback signal 36 to the PMIC 12. The feedback signal 36 enables the PMIC 12 to adjust the low-frequency current I_{DC} and/or the low-frequency voltage V_{DC} accordingly. The control circuit 34 may be coupled to a transceiver circuit 38 that generates the RF signal 18. In this regard, the control circuit 34 may be able to determine the modulation bandwidth of the RF signal 18 and, thus, the different power management modes based on an indication 40 from the transceiver circuit 38.

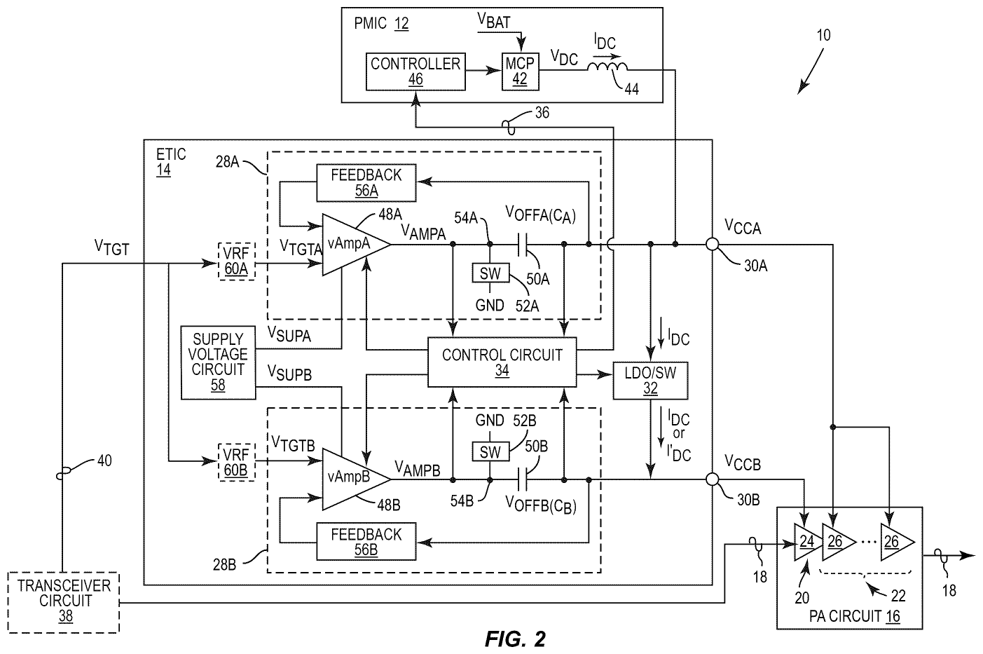

FIG. 2 is a schematic diagram illustrating a detailed configuration of the multi-mode power management apparatus 10 of FIG. 1 in the different power management modes. Common elements between FIGS. 1 and 2 are shown therein with common element numbers and will not be re-described herein.

In a non-limiting example, the PMIC 12 includes a multi-level charge pump (MCP) 42 configured to generate the low-frequency voltage V_{DC} at multiple levels based on a battery voltage V_{BAT} (e.g., 0×V_{BAT}, 1×V_{BAT}, or 2×V_{BAT}). The PMIC 12 also includes a power inductor 44 configured to induce the low-frequency current I_{DC} based on the low-frequency voltage V_{DC}. The PMIC 12 further includes a controller 46, which can be any type of microcontroller or microprocessor, as an example. The controller 46 receives the feedback signal 36 from the control circuit 34 in the ETIC 14. Accordingly, the controller 46 can control the MCP 42 to adjust the low-frequency voltage V_{DC} and, thus, adjust the low-frequency current I_{DC} accordingly.

The first voltage circuit 28A includes a first voltage amplifier 48A (denoted as “vAmpA”) configured to generate a first initial ET voltage V_{AMPA} based on a first ET target voltage V_{TGTA} and a first supply voltage V_{SUPA}. In this regard, the first initial ET voltage V_{AMPA} can correspond to a time-variant voltage envelope that tracks (e.g., rises and falls) a time-variant target envelope of the first ET target voltage V_{TGTA}. The first supply voltage V_{SUPA} may be adjusted to cause the first voltage amplifier 48A to adjust amplitude of the first initial ET voltage V_{AMPA} and thus adjust amplitude of the first ET voltage V_{CCA}.

The first voltage circuit 28A also includes a first offset capacitor 50A having a first capacitance C_{A} (e.g., 4.7 μF) coupled between the first voltage amplifier 48A and the first node 30A. The first offset capacitor 50A is configured to raise the first initial ET voltage V_{AMPA} by a first offset voltage V_{OFFA} (e.g., 0.8 V) to generate the first ET voltage V_{CCA}(V_{CCA}=V_{AMPA}+V_{OFFA}).

The first voltage circuit 28A also includes a first switch 52A (denoted as “SW”) coupled between a first coupling node 54A and a ground (GND). The first voltage circuit 28A further includes a first feedback loop 56A configured to provide a feedback of the first ET voltage V_{CCA} to the first voltage amplifier 48A.

The second voltage circuit 28B includes a second voltage amplifier 48B (denoted as “vAmpB”) configured to generate a second initial ET voltage V_{AMPB} based on a second ET target voltage V_{TGTB} and a second supply voltage V_{SUPB}. In this regard, the second initial ET voltage V_{AMPB} can correspond to a time-variant voltage envelope that tracks (e.g., rises and falls) a time-variant target envelope of the second ET target voltage V_{TGTB}. The second supply voltage V_{SUPB} may be adjusted to cause the second voltage amplifier 48B to adjust amplitude of the second initial ET voltage V_{AMPB} and thus adjust amplitude of the second ET voltage V_{CCB}.

The second voltage circuit 28B also includes a second offset capacitor 50B having a second capacitance C_{B} (e.g., 10-100 nF) coupled between the second voltage amplifier 48B and the second node 30B. The second offset capacitor 50B is configured to raise the second initial ET voltage V_{AMPB} by a second offset voltage V_{OFFB} (e.g., 0.8 V) to generate the second ET voltage V_{CCB}(V_{CCB}=V_{AMPB}+V_{OFFB}).

The second voltage circuit 28B also includes a second switch 52B (denoted as “SW”) coupled between a second coupling node 54B and the GND. The second voltage circuit 28B further includes a second feedback loop 56B configured to provide a feedback of the second ET voltage V_{CCB} to the second voltage amplifier 48B.

The ETIC 14 includes a supply voltage circuit 58 configured to generate the first supply voltage V_{SUPA} and the second supply voltage V_{SUPB}. In a non-limiting example, the supply voltage circuit 58 can generate each of the first supply voltage V_{SUPA} and the second supply voltage V_{SUPB} at multiple levels to help maintain efficiency and linearity of the first voltage amplifier 48A and the second voltage amplifier 48B.

The ETIC 14 may include a first voltage equalizer circuit 60A (denoted as “VRF”) and a second voltage equalizer circuit 60B (denoted as “VRF”). The first voltage equalizer circuit 60A is configured to generate the first ET target voltage V_{TGTA} based on a common ET target voltage V_{TGT}. The second voltage equalizer circuit is configured to generate the second ET target voltage V_{TGTB} based on the common ET target voltage V_{TGT}. The common ET target voltage V_{TGT} is so generated to have a time-variant voltage envelope that tracks (rises and falls) a time-variant signal envelope of the RF signal 18.

In one embodiment, in the first power management mode, the control circuit 34 is configured to cause the first node 30A to output the first ET voltage V_{CCA} and the low-frequency current I_{DC}. The control circuit 34 is also configured to cause the second node 30B to output the second ET voltage V_{CCB} and an adjusted low-frequency current I′_{DC} that is proportional to the low-frequency current I_{DC}. In this regard, the driver stage 20 is receiving the second ET voltage V_{CCB} and the adjusted low-frequency current I′_{DC}, while the output stage 22 is receiving the first ET voltage V_{CCA} and the low-frequency current I_{DC}.

Notably, the RF signal 18 has been amplified by the power amplifier 24 in the driver stage 20 when the RF signal 18 reaches the output stage 22. As such, the RF signal 18 will correspond to a higher amplitude at the output stage 22 than at the driver stage 20. As such, the first ET voltage V_{CCA} needs to be greater than or equal to the second ET voltage V_{CCB}(V_{CCA}≥V_{CCB}) to prevent the RF signal 18 from being distorted at the output stage 22 (e.g., due to amplitude clipping).

More specifically, the control circuit 34 activates the first voltage amplifier 48A and the second voltage amplifier 48B to cause the first node 30A and the second node 30B to output the first ET voltage V_{CCA} and the second ET voltage V_{CCB}, respectively. The control circuit 34 controls the LDO regulator in the multifunction circuit 32 to generate the adjusted low-frequency current I′_{DC}. The control circuit 34 also closes the switch in the multifunction circuit 32 to provide the adjusted low-frequency current I′_{DC} to the second node 30B. The control circuit 34 further opens the first switch 52A and the second switch 52B to cause the first node 30A and the second node 30B to output the low-frequency current I_{DC} and the adjusted low-frequency current I′_{DC}, respectively.

The control circuit 34 may determine a voltage differential across the first offset capacitor 50A (e.g., a difference between V_{CCA} and V_{AMPA}). The voltage differential across the first offset capacitor 50A may serve as an indication of surplus or shortfall of the low-frequency current I_{DC} at the first node 30A. Accordingly, the control circuit 34 generates the feedback signal 36 based on the voltage differential. Accordingly, the controller 46 in the PMIC 12 can control the MCP 42 based on the feedback signal 36 to cause the low-frequency voltage V_{DC} and the low-frequency current I_{DC} to decrease or increase.

The control circuit 34 may determine a voltage differential across the second offset capacitor 50B (e.g., a difference between V_{CCB} and V_{AMPB}). The voltage differential across the second offset capacitor 50B may serve as an indication of surplus or shortfall of the adjusted low-frequency current I′_{DC} at the second node 30B. Accordingly, the control circuit 34 may control the LDO regulator in the multifunction circuit 32 to decrease or increase the adjusted low-frequency current I′_{DC}.

Notably, when the RF signal 18 progresses trough the driver stage 20 and the output stage 22 of the multi-stage power amplifier circuit 16, the RF signal 18 can experience a temporal delay between the driver stage 20 and the output stage 22. As a result, the RF signal 18 can experience an instantaneous amplitude variation between the driver stage 20 and the output stage 22. In this regard, the first voltage equalizer circuit 60A and the second voltage equalizer circuit 60B can be configured to delay the first ET target voltage V_{TGTA} from the second ET target voltage V_{TGTB} by a determined temporal delay between the driver stage 20 and the output stage 22 of the multi-stage power amplifier circuit 16. As a result, the second ET voltage V_{CCB} will be delayed from the first ET voltage V_{CCA} by the determined temporal delay, thus helping to accommodate the temporal delay between the driver stage 20 and the output stage 22.

In another embodiment, in the second power management mode, the control circuit 34 is configured to cause the first node 30A and the second node 30B to each output the first ET voltage V_{CCA} and the low-frequency current I_{DC}. Specifically, the control circuit 34 activates the first voltage amplifier 48A and deactivates the second voltage amplifier 48B to cause the first node 30A and the second node 30B to each output the first ET voltage V_{CCA}. The control circuit 34 also disables the LDO regulator and closes the switch in the multifunction circuit 32 to couple the second node 30B to the first node 30A to receive the low-frequency current I_{DC}. The control circuit 34 further opens the first switch 52A and the second switch 52B to cause the first node 30A and the second node 30B to each output the low-frequency current I_{DC}. The control circuit 34 is further configured to generate the feedback signal 36 based on the voltage differential across the first offset capacitor 50A.

In another embodiment, in the third power management mode, the control circuit 34 is configured to cause the first node 30A and the second node 30B to each output the second ET voltage V_{CCB} and the low-frequency current I_{DC}. Specifically, the control circuit 34 deactivates the first voltage amplifier 48A and activates the second voltage amplifier 48B to cause the first node 30A and the second node 30B to each output the second ET voltage V_{CCB}. The control circuit 34 also disables the LDO regulator and closes the switch in the multifunction circuit 32 to couple the second node 30B to the first node 30A to receive the low-frequency current I_{DC}. The control circuit 34 further opens the first switch 52A and the second switch 52B to cause the first node 30A and the second node 30B to each output the low-frequency current I_{DC}. The control circuit 34 is further configured to generate the feedback signal 36 based on the voltage differential across the first offset capacitor 50A.

In another embodiment, in the fourth power management mode, the control circuit 34 is configured to cause the first node 30A and the second node 30B to each output the low-frequency voltage V_{DC} and the low-frequency current I_{DC}. Specifically, the control circuit 34 deactivates the first voltage amplifier 48A and the second voltage amplifier 48B. As a result, none of the first ET voltage V_{CCA} and the second ET voltage V_{CCB} will be generated. The control circuit 34 also disables the LDO regulator and closes the switch in the multifunction circuit 32 to couple the second node 30B to the first node 30A to receive the low-frequency current I_{DC}. The control circuit 34 further closes the first switch 52A and opens the second switch 52B such that the low-frequency voltage V_{DC} at the first node 30A and the second node 30B is modulated across the first offset capacitor 50A to track an average power of the RF signal 18. In this regard, the low-frequency voltage V_{DC} can be referred to as an average power tracking (APT) voltage. The control circuit 34 is further configured to generate the feedback signal 36 based on the voltage differential across the first offset capacitor 50A and the PMIC 12 can modulate the low-frequency current IDC accordingly. As a result, both the driver stage 20 and the output stage 22 will operate based on the low-frequency voltage V_{DC} and the low-frequency current I_{DC}.

In another embodiment, in the fifth power management mode, the control circuit 34 is configured to cause the first node 30A and the second node 30B to each output the low-frequency voltage V_{DC} and the low-frequency current I_{DC}. Specifically, the control circuit 34 deactivates the first voltage amplifier 48A and the second voltage amplifier 48B. As a result, none of the first ET voltage V_{CCA} and the second ET voltage V_{CCB} will be generated. The control circuit 34 also disables the LDO regulator and closes the switch in the multifunction circuit 32 to couple the second node 30B to the first node 30A to receive the low-frequency current I_{DC}. The control circuit 34 further opens the first switch 52A and closes the second switch 52B such that the low-frequency voltage V_{DC} at the first node 30A and the second node 30B is modulated across the second offset capacitor 50B to track the average power of the RF signal 18. In this regard, the low-frequency voltage V_{DC} is also the APT voltage. The control circuit 34 is further configured to generate the feedback signal 36 based on the voltage differential across the first offset capacitor 50A and the PMIC 12 can modulate the low-frequency current I_{DC} accordingly. As a result, both the driver stage 20 and the output stage 22 will operate based on the low-frequency voltage V_{DC} and the low-frequency current I_{DC}.

Those skilled in the art will recognize improvements and modifications to the preferred embodiments of the present disclosure. All such improvements and modifications are considered within the scope of the concepts disclosed herein and the claims that follow.

What is claimed is:

1. A method for operating a multi-mode power management apparatus comprising:
generating a low-frequency current and a low-frequency voltage;
generating a first ET voltage based on a first ET target voltage;
generating a second ET voltage based on a second ET target voltage;
outputting one or more of the first ET voltage, the second ET voltage, and the low-frequency voltage via a first node and a second node;
outputting at least the low-frequency current via the first node and the second node; and
delaying the first ET target voltage from the second ET target voltage to accommodate for a temporal delay inside a multi-stage power amplifier circuit that amplifies a radio frequency (RF) signal.

2. The method of claim 1 further comprising, in a first power management mode:
outputting, via the first node, the first ET voltage and the low-frequency current; and
outputting, via the second node, the second ET voltage less than or equal to the first ET voltage and an adjusted low-frequency current proportional to the low-frequency current.

3. The method of claim 1 further comprising, in a third power management mode, outputting the first ET voltage and the low-frequency current via each of the first node and the second node.

4. The method of claim 1 further comprising, in a second power management mode, outputting, via each of the first node and the second node, the second ET voltage and the low-frequency current.

5. The method of claim 1 further comprising, in a fourth power management mode, outputting, via each of the first node and the second node, the low-frequency voltage and the low-frequency current.

6. The method of claim 1, further comprising delaying the first ET target voltage from the second ET target voltage to thereby accommodate for the temporal delay between a driver stage and an output stage in the multi-stage power amplifier circuit.

7. The method of claim 6 further comprising:
generating the low-frequency voltage based on a battery voltage;
inducing the low-frequency current based on the low-frequency voltage; and
adjusting the low-frequency voltage and the low-frequency current based on a feedback signal.

8. The method of claim 7 further comprising:
generating, via a first voltage amplifier, a first initial ET voltage at a first coupling node based on the first ET target voltage;
raising, via a first offset capacitor, the first initial ET voltage by a first offset voltage to generate the first ET voltage;
generating, via a second voltage amplifier, a second initial ET voltage at a second coupling node based on the second ET target voltage; and
raising, via a second offset capacitor, the second initial ET voltage by a second offset voltage to generate the second ET voltage.

9. The method of claim 8 further comprising:
generating a multi-level supply voltage for one or more of the first voltage amplifier and the second voltage amplifier;
generating the first ET target voltage based on a common ET target voltage; and
generating the second ET target voltage based on the common ET target voltage.

10. The method of claim 8 further comprising, in a first power management mode:
activating the first voltage amplifier and the second voltage amplifier to cause the first node and the second node to output the first ET voltage and the second ET voltage, respectively;
controlling a multifunction circuit coupled between the first node and the second node to generate an adjusted low-frequency current proportional to the low-frequency current; and
opening a first switch coupled between the first coupling node and a ground and a second switch coupled between the second coupling node and the ground to thereby cause the first node and the second node to output the low-frequency current and the adjusted low-frequency current, respectively.

11. The method of claim 10 further comprising:
generating the feedback signal based on a respective voltage differential across the first offset capacitor; and
controlling the multifunction circuit based on a respective voltage differential across the second offset capacitor.

12. The method of claim 10 further comprising delaying the first ET target voltage from the second ET target voltage based on a determined temporal delay between the driver stage and the output stage of the multi-stage power amplifier circuit.

13. The method of claim 8 further comprising, in a second power management mode:
activating the first voltage amplifier and deactivating the second voltage amplifier to cause the first node and the second node to each output the first ET voltage;
controlling a multifunction circuit coupled between the first node and the second node to couple the second node to the first node to receive the low-frequency current; and
opening a first switch coupled between the first coupling node and a ground and a second switch coupled between the second coupling node and the ground to cause the first node and the second node to each output the low-frequency current.

14. The method of claim 13 further comprising generating the feedback signal based on a voltage differential across the first offset capacitor.

15. The method of claim 8 further comprising, in a second power management mode:
deactivating the first voltage amplifier and activating the second voltage amplifier to cause the first node and the second node to each output the second ET voltage;
controlling a multifunction circuit coupled between the first node and the second node to couple the second node to the first node to receive the low-frequency current; and
opening a first switch coupled between the first coupling node and a ground and a second switch coupled between the second coupling node and the ground to cause the first node and the second node to each output the low-frequency current.

16. The method of claim 15 further comprising generating the feedback signal based on a voltage differential across the first offset capacitor.

17. The method of claim 8 further comprising, in a second power management mode:
deactivating the first voltage amplifier and the second voltage amplifier;
controlling a multifunction circuit coupled between the first node and the second node to couple the second node to the first node to receive the low-frequency current; and
closing a first switch coupled between the first coupling node and a ground and opening a second switch coupled between the second coupling node and the ground to cause the low-frequency voltage to be modulated across the first offset capacitor.

18. The method of claim 17 further comprising generating the feedback signal based on a voltage differential across the first offset capacitor.

19. The method of claim 8 further comprising, in a second power management mode:
deactivating the first voltage amplifier and the second voltage amplifier;
controlling a multifunction circuit coupled between the first node and the second node to couple the second node to the first node to receive the low-frequency current; and
opening a first switch coupled between the first coupling node and a ground and closing a second switch coupled between the second coupling node and the ground to cause the low-frequency voltage to be modulated across the second offset capacitor.

20. The method of claim 19 further comprising generating the feedback signal based on a voltage differential across the first offset capacitor.

21. A wireless device comprising a multi-mode power management apparatus, the multi-mode power management apparatus comprises:
a power management integrated circuit (PMIC) configured to generate a low-frequency current and a low-frequency voltage;
an envelope tracking (ET) integrated circuit (ETIC) comprising:
a first node coupled to the PMIC;
a second node coupled to the first node via a multifunction circuit;
a first voltage circuit configured to generate a first ET voltage based on a first ET target voltage;
a second voltage circuit configured to generate a second ET voltage based on a second ET target voltage; and
a control circuit configured to:
cause the first node and the second node to output one or more of the first ET voltage, the second ET voltage, and the low-frequency voltage; and
cause the first node and the second node to output at least the low-frequency current; and
a multi-stage power amplifier circuit coupled to the first node and the second node and configured to amplify a radio frequency (RF) signal, wherein the first ET target voltage is delayed from the second ET target voltage to accommodate for a temporal delay inside the multi-stage power amplifier circuit.
